(19) United States
(12) Patent Application Publication
(10) Pub. No.: US 2001/0005613 A1
(43) Pub. Date: Jun. 28, 2001

(54) Semiconductor device and method of fabricating the same

(76) Inventor: Naoto Akiyama, Tokyo (JP)

Correspondence Address: SUGHRUE, MION, ZINN, MACPEAK & SEAS, 2100 Pennsylvania Avenue, N.W., Washington, DC, 20037, US

(21) Appl. No.: 09/740,992

(22) Filed: Dec. 21, 2000

(30) Foreign Application Priority Data
Dec. 22, 1999 (JP) 11-363687

(51) Int. Cl. H01L 21/8236; H01L 21/336; H01L 31/062

(52) U.S. Cl. 438/276; 438/291; 438/275; 257/390; 257/391; 257/392

(57) ABSTRACT

First NMOS and PMOS transistors for operating high speed, and second NMOS and PMOS transistors for reducing a leak current in an off state, are formed on the same p-type substrate. In a fabricating method, Boron is ion-implanted to the first and second NMOS transistor forming regions of the surface of the substrate to form p well. Subsequently, boron is ion-implanted to only the second NMOS transistor forming region additionally for threshold voltage adjustment to minimize the off-state leak current. Arsenic is ion-implanted to the first and second PMOS transistor forming regions of the surface of the substrate to form n well. Subsequently, Arsenic is ion-implanted only to the second PMOS transistor forming region additionally for threshold voltage adjustment to minimize the off-state leak current.

### BACKGROUND OF THE INVENTION

1. Field of the Invention

The present invention relates to a semiconductor device and a method of fabricating the same and, more particularly, to a semiconductor device in which MOS (Metal Oxide Semiconductor) transistors having different threshold voltages are formed on the same substrate and a leak current when the MOS transistors are OFF (hereinbelow, also referred to as an off-state leak current) is reduced and a method of fabricating the semiconductor device.

2. Description of the Related Art

One of important factors in an LSI (Large-Scale Integrated) circuit intended to perform an operation with low power consumption is a reduced off-state leak current of each MOS transistor.

In order to reduce the off-state leak current, usually, a method of setting a threshold of an MOS transistor to a high value is adopted. Generally disclosed specific methods of increasing a threshold in a MOS transistor include a method of making the gate length of a gate electrode long, a method of increasing concentration of impurities in a channel region, and a method of controlling a substrate bias.

When any of the methods is simply applied to a MOS transistor, however, it causes deterioration in driving capability of the MOS transistor. It cannot be therefore said that the methods are sufficient with respect to a point of maintaining a high-speed operation of an LSI.

For example, as disclosed in Japanese Patent Application Laid-Open No. 11-195976, there is a method of increasing a threshold only of a MOS transistor in a specific region on a circuit. The conventional technique aims at reducing the off-state leak current of a MOS transistor in a specific region. A passable effect of realizing low power consumption without considerably deteriorating the operation speed of an LSI is produced.

On the contrary, a finer MOS transistor in recent years has, however, a new problem such that the off-state leak current increases when a high threshold is set. The reason of occurrence of the problem is that, in a MOS transistor which is made finer by a scaling rule, in addition to a conventional sub-threshold leak or diffusion layer leak, an interband leak current flowing between a gate electrode and a channel appears conspicuously.

A phenomenon such that a diffusion layer leak component increases by increasing the threshold is disclosed in, for example, Japanese Patent Application Laid-Open No. 10-247725.

FIG. 1 is a graph showing a gate voltage-drain current characteristic of a conventional NMOS transistor, in which the lateral line indicates a gate voltage and the vertical line indicates a common logarithm of a drain current. As shown in FIG. 1, a dominant component of an off-state leak current I_{off} of a conventional MOS transistor is a sub-threshold current. The leak current can be effectively reduced by increasing the threshold.

FIG. 2 is a graph showing a gate voltage-drain current characteristic of a fine NMOS transistor, in which the lateral line indicates a gate voltage and the vertical line indicates a common logarithm of a drain current. In a fine MOS transistor, however, as shown in FIG. 2, when the concentration of impurities in a channel region is increased to thereby increase the threshold, the dominant component of the off-state leak current I_{off} changes from the threshold current to an interband leak current. As a result, a problem such that the off-state leak current increases again occurs.

In the case of increasing the threshold by making the gate length longer, similarly, the dominant component of the off-state leak current changes from the sub-threshold current to the interband leak current. Consequently, the off-state leak current increases again at a minimum value.

FIG. 3 is a graph showing a leak current characteristic of a fine NMOS transistor when a threshold voltage is off state, in which the lateral line indicates a threshold voltage and the vertical line indicates an off state leak current. As described above, in the case where the threshold is set to a high value by increasing the concentration of a channel, making the gate length longer, and the like, as shown in FIG. 3, the dominant component of the off-state leak current changes from the sub-threshold leak current to the interband leak current. That is, since the sub-threshold leak current decreases as the threshold voltage rises, the value of the off-state leak current decreases to the minimum value. When the threshold increases further, the dominant component of the off-state leak current changes to the interband leak, thereby increasing the off-state leak current again.

Adaptation to the method of controlling a substrate bias will be examined. When the dominant component of the off-state leak current is a sub-threshold current, by applying a substrate bias to increase the threshold, the off-state leak current can be effectively reduced. FIG. 4 is a graph showing a substrate bias-off-state leak current characteristic of a fine NMOS transistor, in which the lateral line indicates a gate voltage and the vertical line indicates a common logarithm of the drain current. In FIG. 4, the order of application of the substrate bias is, from highest to lowest, broken line, alternate long and short dash line. However, it is understood from FIG. 4 that, when the interband leak is becoming a dominant component, the minimum value of the drain current (value at which the dominant component of the off-state leak current changes from the sub-threshold current to the interband leak current) is not largely reduced even if the substrate bias is controlled but, on the contrary, may be increased.

As described above, in any of the method of increasing the concentration of impurities in a channel region, the method of making the gate length longer, the method of controlling the substrate bias, and the like, an effect on reducing the off-state leak current by increasing the threshold is determined by the interband leak current. Consequently, it can be said that there is a limit value in practical use.

### SUMMARY OF THE INVENTION

The object of the invention is to provide a semiconductor device suitable for a low-power consumption operation, having a transistor intended to operate with low power consumption and a transistor intended to operate at high speed on the same substrate, in which a leak current in a state where a MOS transistor is OFF is reduced.

A semiconductor device according to a first aspect of the present invention comprises a first MOS transistor and a second MOS transistor formed on a same substrate, the second MOS transistor having a threshold higher than that of the first MOS transistor. In the second MOS transistor, concentration of impurities in a channel region is set so that a minimum drain current appearing at the time of transition from a sub-threshold leak to an interband leak is a leak current in an off-state of the second MOS transistor.

A semiconductor device according to a second aspect of the present invention comprises a first MOS transistor and a second MOS transistor formed on a same substrate, the second MOS transistor having a threshold higher than that of the first MOS transistor. In the second MOS transistor, gate length is set so that a minimum drain current appearing at the time of transition from a sub-threshold leak to an interband leak is a leak current in an off-state of the second MOS transistor.

A semiconductor device according to a third aspect of the present invention comprises a first MOS transistor and a second MOS transistor formed on a same substrate, the second MOS transistor having a threshold higher than that of the first MOS transistor. In the second MOS transistor, concentration of impurities in a channel region and gate length are set so that a minimum drain current appearing at the time of transition from a sub-threshold leak to an interband leak is a leak current in an off-state of the second MOS transistor.

A method of fabricating a semiconductor device according to a first aspect of the present invention in which a first MOS transistor and a second MOS transistor which operates with a threshold higher than that of the first MOS transistor are formed on the same substrate, comprises the step of setting concentration of impurities in a channel region in the second MOS transistor so that a minimum drain current appearing at the time of transition from a sub-threshold leak to an interband leak is a leak current in an off-state of the second MOS transistor.

A method of fabricating a semiconductor device according to a second aspect of the present invention in which a first MOS transistor and a second MOS transistor operating with a threshold higher than that of the first MOS transistor are formed on the same substrate, comprises the step of setting gate length of the second MOS transistor so that a minimum drain current appearing at the time of transition from a sub-threshold leak to an interband leak is a leak current in an off-state of the second MOS transistor.

A method of fabricating a semiconductor device according to a third aspect of the present invention in which a first MOS transistor and a second MOS transistor operating with a threshold higher than that of the first MOS transistor are formed on the same substrate, comprises the step of setting concentration of impurities in a channel region and gate length in the second MOS transistor so that a minimum drain current appearing at the time of transition from a sub-threshold leak to an interband leak is a leak current in an off-state of the second MOS transistor.

That is, the semiconductor device of the invention has a configuration such that a first MOS transistor operating with a low threshold, intended to operate high speed for use in a circuit portion and a second MOS transistor operating with a high threshold intended to reduce a leak current occurring in an off-state of the second MOS transistor are formed on the same substrate. The semiconductor device is characterized in that, in the second MOS transistor operating with a high threshold, concentration of impurities in a channel region and/or gate length are/is set so that the minimum drain current is the leak current in the off-state of the second MOS transistor.

In the present invention, by adjusting the concentration of impurities in the channel region and/or the gate length so that the minimum drain current of the second MOS transistor operating with a high threshold is the leak current in the off-state of the transistor, the threshold of the second MOS transistor is set. That is, by setting the threshold of the second transistor operating with a high threshold so as to minimize the off-state leak current, even when a substrate bias is not applied, an effect of sufficiently reducing the leak current can be obtained. In spite of variations in the threshold and the like caused by a fabricating process such as fluctuation in gate length, the off-state leak current value is stable and an almost minimum value can be obtained. Thus, a semiconductor device of a low power consumption can be obtained.

The interband leak referred to in the invention has a characteristic such that it increases as the gate voltage is decreased. A phenomenon such that a diffusion layer leak component increases when the threshold is raised conspicuously occurs, mainly in a fine MOS transistor in the generation of a design rule of 0.25 μm and after that in which the concentration of impurities in both the channel region and the drain region is high.

### BRIEF DESCRIPTION OF THE DRAWINGS

FIG. 1 is a graph showing a gate voltage-drain current characteristic of a conventional NMOS transistor, in which the lateral line indicates a gate voltage and the vertical line indicates a common logarithm of a drain current.

FIG. 2 is a graph showing a gate voltage-drain current characteristic of a fine NMOS transistor, in which the lateral line indicates a gate voltage and the vertical line indicates a common logarithm of a drain current.

FIG. 3 is a graph showing a leak current characteristic of a fine NMOS transistor when a threshold voltage is off state, in which the lateral line indicates a threshold voltage and the vertical line indicates an off state leak current.

FIG. 4 is a graph showing a substrate bias-off-state leak current characteristic of a fine NMOS transistor, in which the lateral line indicates a gate voltage and the vertical line indicates a common logarithm of a drain current.

FIGS. 5A to 5J are cross sectional views showing a method of fabricating a semiconductor device according to a first embodiment of the invention.

FIG. 6 is a graph showing a gate voltage-drain current characteristic of a MOS transistor, in which the lateral line denotes a gate voltage, the vertical line indicates a common logarithm of a drain current, and a threshold is set so that the minimum value of the drain current of the invention is an off-state leak current.

FIG. 7 is a cross sectional view showing a semiconductor device according to a second embodiment of the invention.

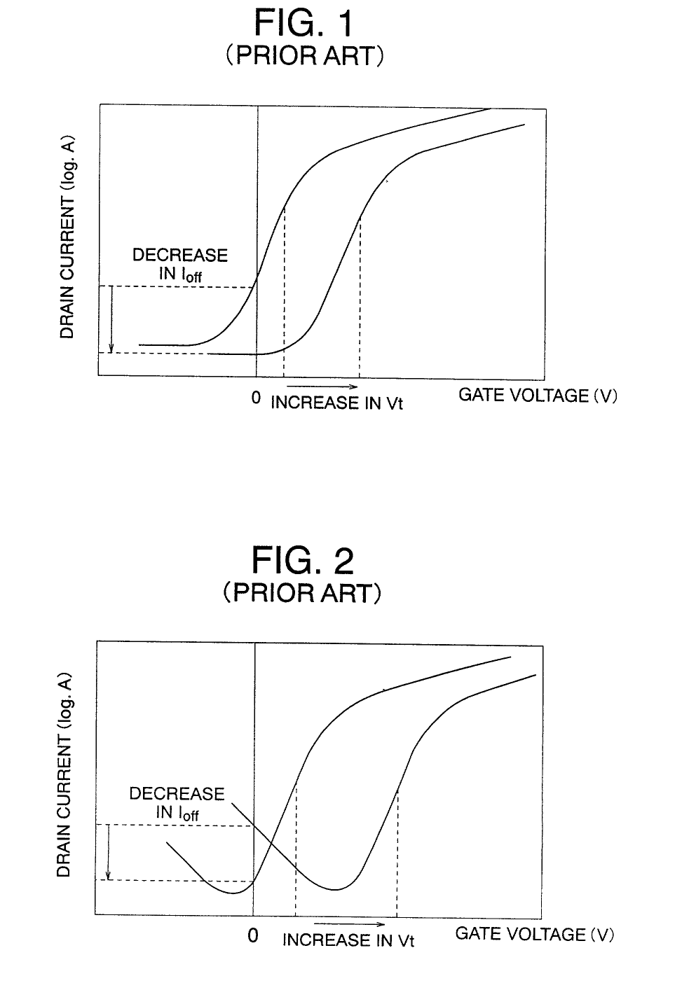

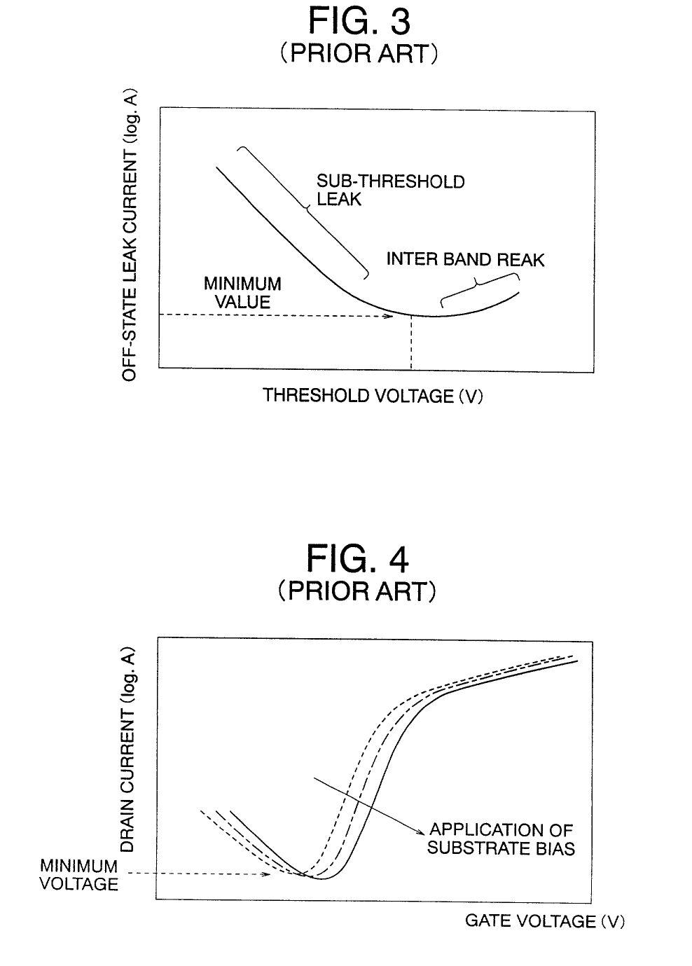

### DETAILED DESCRIPTION OF THE PREFERRED EMBODIMENTS

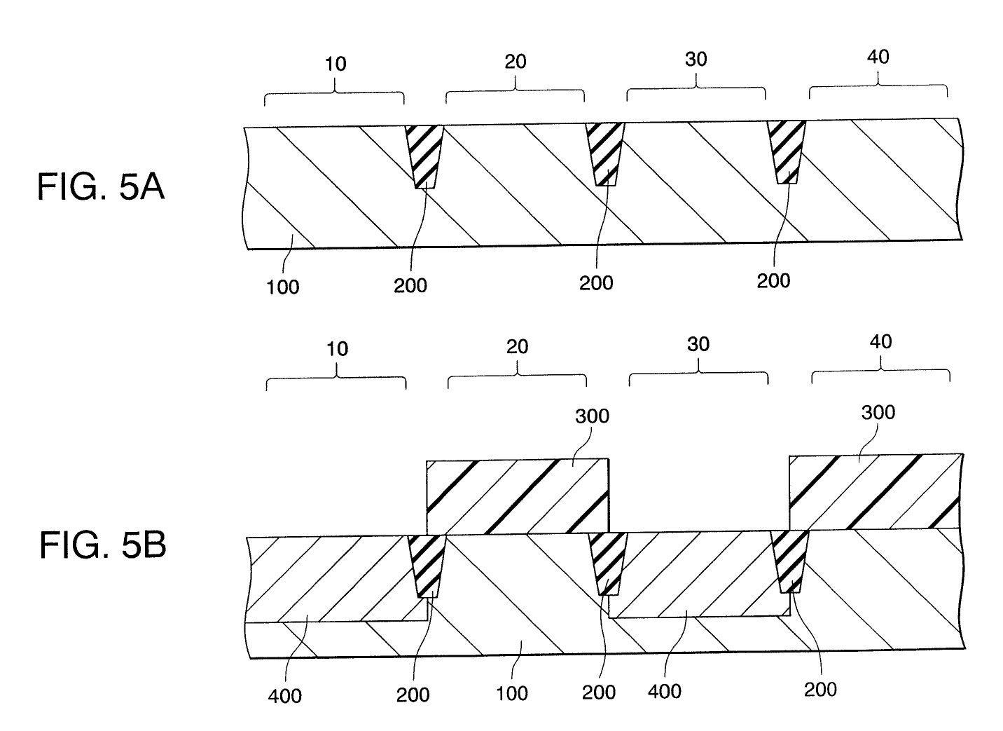

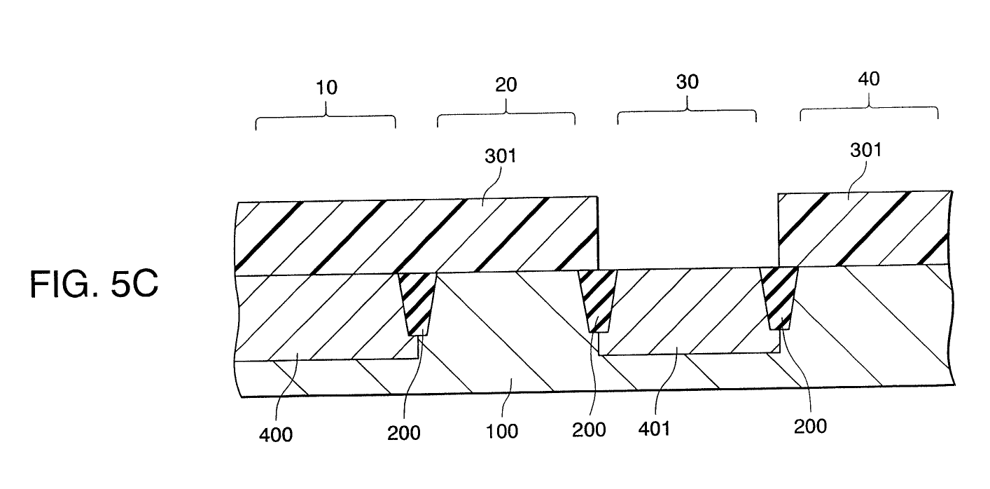

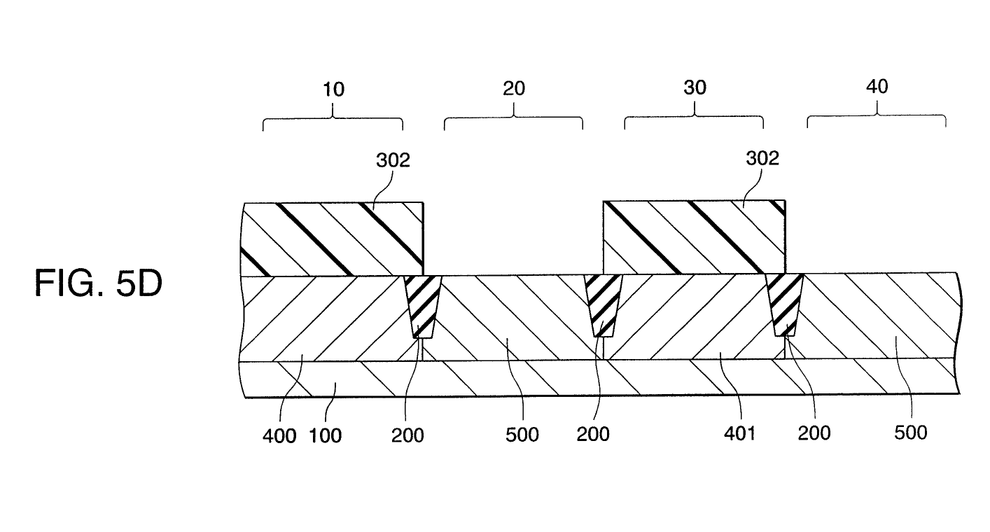

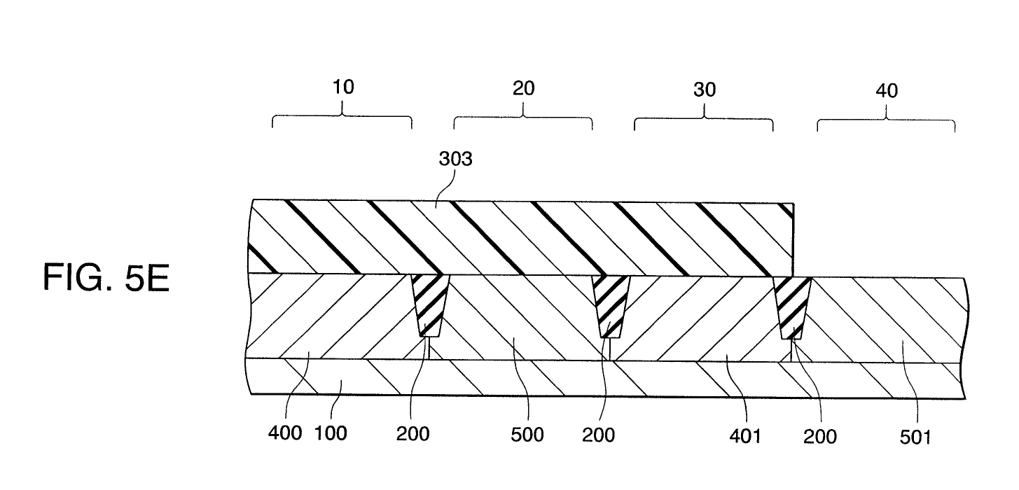

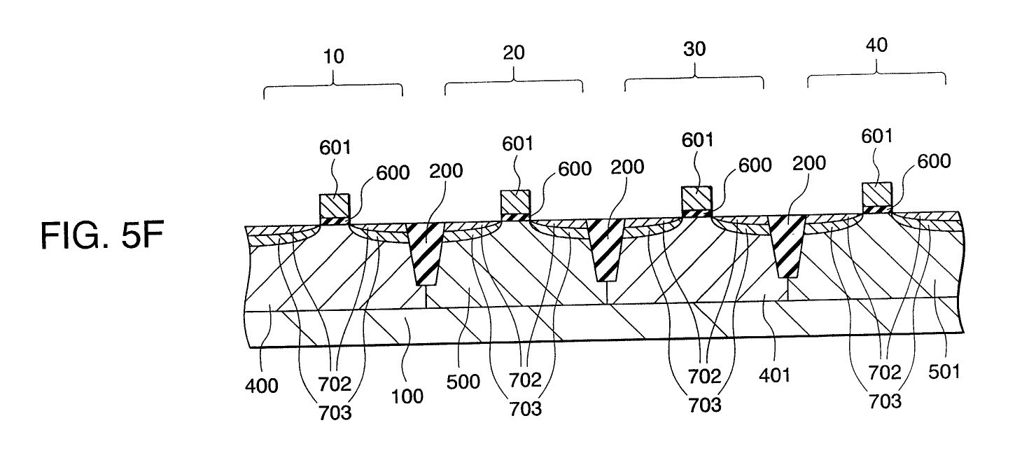

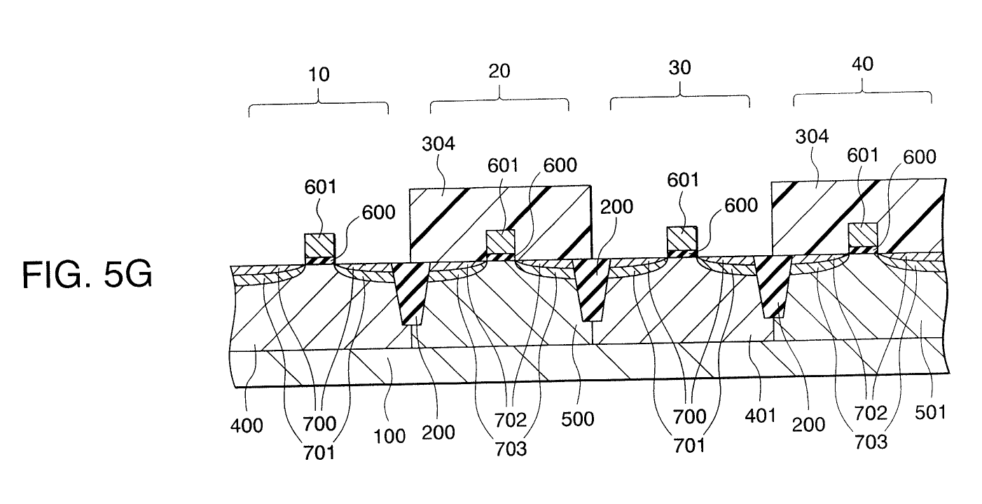

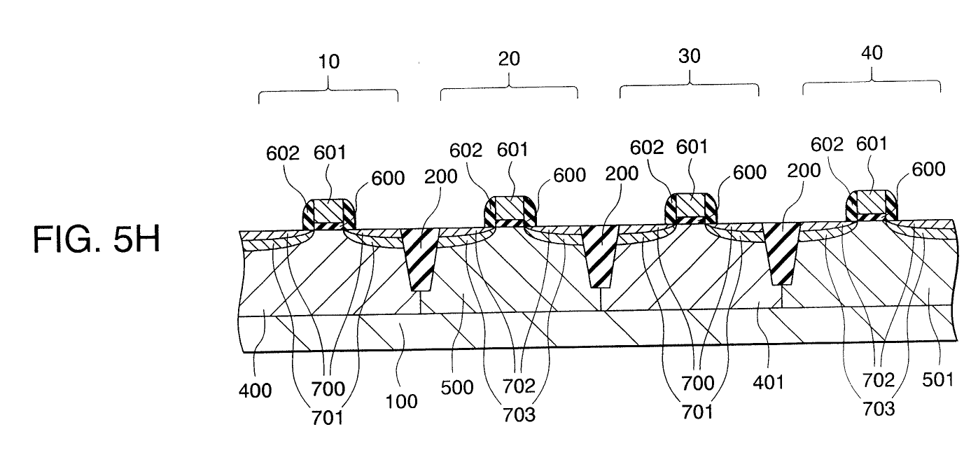

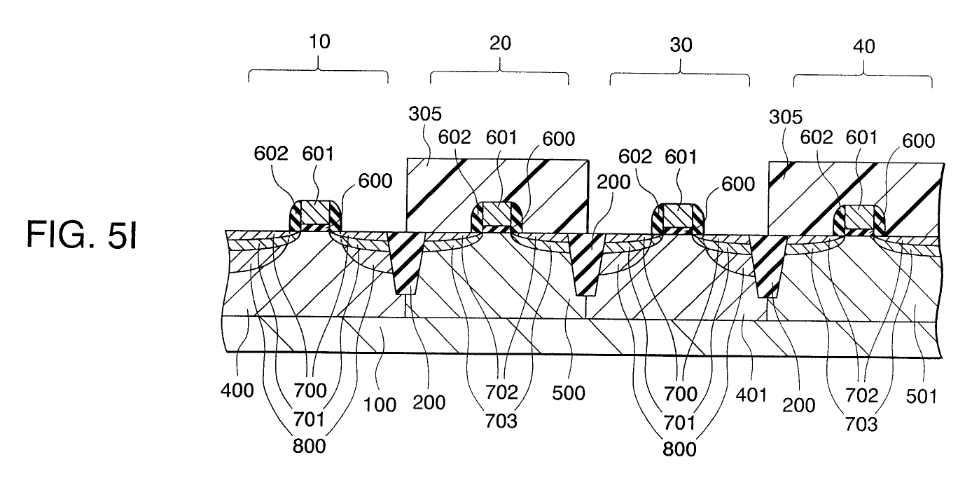

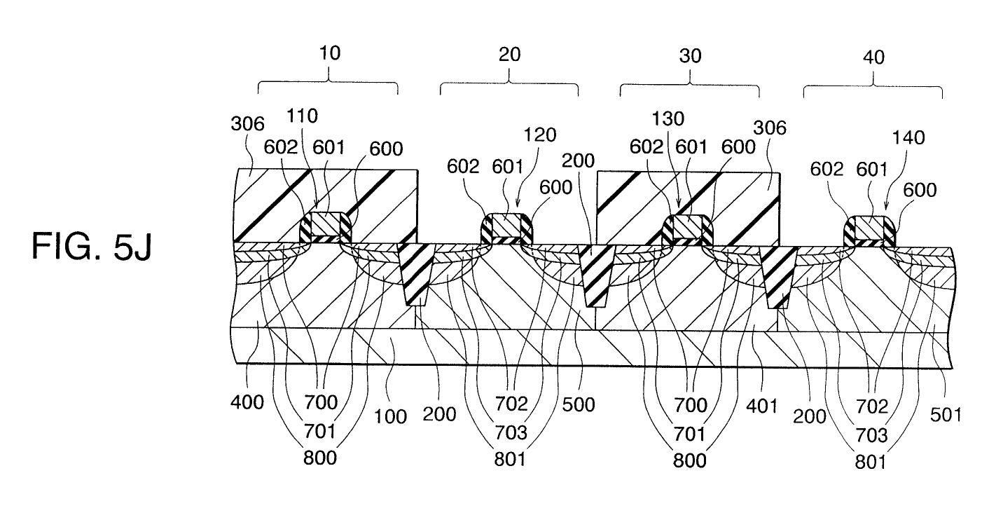

Embodiments of the present invention will be described in detail hereinbelow with reference to the accompanying drawings. FIG. 5J is a cross sectional view showing a semiconductor device according to a first embodiment of the invention. Although a resist 306 is formed in FIG. 5J, in the semiconductor device of the embodiment, the resist 306 is removed.

As shown in FIG. 5J, a plurality of device isolation regions (selective oxidation film) 200 are formed in the surface of a P-type silicon substrate 100, thereby defining device formation regions 10, 20, 30 and 40. In the surface of the silicon substrate 100 of the device formation regions 10 and 30, a p-well 400 and a p-well 401 are formed, respectively. Ion implantation is repeated into the p-well 401 and the concentration of impurities in the p-well 401 is adjusted. In predetermined positions on the p-wells 400 and 401, a gate oxide film 600 and a gate electrode 601 are formed. Side walls 602 are formed on side faces of the gate oxide film 600 and the gate electrode 601. In positions sandwiching the gate electrodes 601 in the surface of the p-wells 400 and 401, LDDs 700, pocket regions 701, and source-drain regions 800 are formed. On the surface of the silicon substrate 100 of the device formation regions 20 and 40, n-wells 500 and 501 are formed, respectively. Ion implantation is repeated to the n-well 501 and the concentration of impurities in the n-well 501 is adjusted. In predetermined positions on the n-wells 500 and 501, the gate oxide film 600 and the gate electrode 601 are formed. Further, the side walls 602 are formed on side faces of the gate oxide film 600 and the gate electrode 601. In positions sandwiching the gate electrodes 601 in the surface of the n-wells 500 and 501, LDDs 702, pocket regions 703, and source-drain regions 801 are formed. In such a manner, in the device formation regions 10, 20, 30, and 40, an NMOS transistor 110 and a PMOS transistor 120 (first MOS transistors) which operate with a low threshold, intended to operate high speed, and an NMOS transistor 130 and a PMOS transistor 140 (second MOS transistors) which operate with a high threshold, intended to reduce a leak current in an OFF state are formed. Each of the transistors is used in a circuit portion.

In the embodiment, the semiconductor device has the NMOS transistor 110 and the PMOS transistor 120 which operate with a low threshold, and the NMOS transistor 130 and the PMOS transistor 140 in which the impurity concentration of the p-well 401 and the n-well 501 is adjusted. That is, a high-speed operation can be performed and, since the impurity concentration in the channel region in each of the NMOS transistor 130 and the PMOS transistor 140 is adjusted and the threshold is optimized, an off-state leak current is small, and a lower power consumption can be realized.

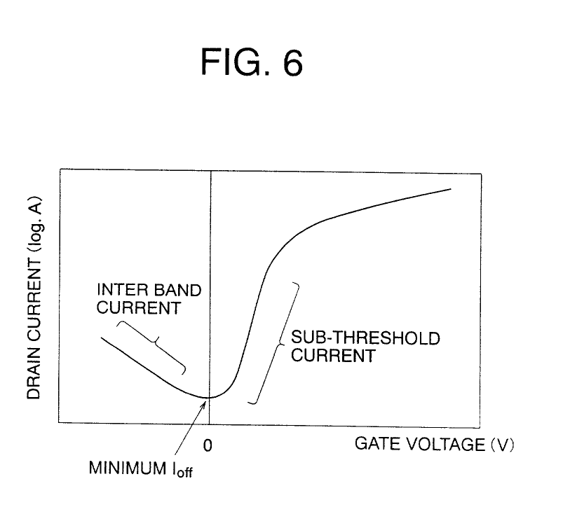

A method of fabricating the semiconductor device according to the embodiment will now be described. FIGS. 5A to 5J are cross sectional views showing the method of fabricating the semiconductor device of the embodiment in accordance with processing order. FIG. 6 is a graph showing a gate voltage-drain current characteristic of an MOS transistor, in which the lateral line indicates a gate voltage, the vertical line indicates a common logarithm of a drain current, and a threshold is set so that the minimum value of the drain current of the invention is an off-state leak current.

First, as shown in FIG. 5A, the surface of the p-type silicon substrate 100 is defined by selective oxidation film 200 having a depth of 250 to 450 nm for device isolation. In FIG. 5A, the regions for forming NMOS transistor and the PMOS transistor which operate with a low threshold for use in an ordinary LSI circuit are indicated by reference numerals 10 and 20, respectively. The regions for forming the NMOS transistor and the PMOS transistor in which the threshold is optimized to minimize the off-state leak current are indicated by reference numerals 30 and 40, respectively.

As shown in FIG. 5B, a resist film 300 is formed on the PMOS transistor forming regions 20 and 40. Boron is ion-implanted once or a plurality of times into the NMOS transistor forming regions 10 and 30 with the parameters of implantation energy of 100 to 400 KeV and an implantation amount of 1×10¹² to 3×10¹³ cm⁻², thereby forming the p-wells 400. Subsequently, with the parameters of implantation energy of 20 to 40 KeV and an implantation amount of 1×10¹² to 1×10¹³ cm⁻², boron is ion-implanted for adjusting a threshold voltage. At the stage shown in FIG. 5B, the transistor forming regions 10 and 30 have the same structure.

Subsequently, as shown in FIG. 5C, a resist film 301 is formed in the region on the substrate 100 except for the transistor forming region 30. Only to the transistor forming region 30, boron is ion-implanted additionally for threshold voltage adjustment to minimize the off-state leak current with the parameters of the implantation energy of 20 to 40 KeV and the implantation amount of 1×10¹² to 2×10¹³ cm⁻², thereby forming the p-well 401. To the transistor forming region 30, therefore, boron is ion-implanted for threshold adjustment with the parameters of the implantation energy of 20 to 40 KeV and the implantation amount of 1×10¹³ to 3×10¹³ cm⁻² as a total.

Further, as shown in FIG. 5D, a resist film 302 is formed on the NMOS transistor forming regions 10 and 30. Phosphorus is ion-implanted once or a plurality of times into the transistor forming regions 20 and 40 with the parameters of implantation energy of 200 to 800 KeV and implantation amount of 1×10¹² to 2×10¹³ cm⁻², thereby forming the n-wells 500. Subsequently, with the parameters of implantation energy of 70 to 120 KeV and the implantation amount of 1×10¹² to 1×10¹³ cm⁻², arsenic is ion-implanted additionally for threshold voltage adjustment. At the stage shown in FIG. 5D, the transistor forming regions 20 and 40 have the same structure.

Subsequently, as shown in FIG. 5E, a resist film 303 is formed on the substrate 100 except for the transistor forming region 40. Only to the transistor forming region 40, arsenic is ion-implanted additionally for threshold voltage adjustment to minimize the off-state leak current with the parameters of the implantation energy of 70 to 120 KeV and the implantation amount 1×10¹² to 2×10¹³ cm⁻², thereby forming the n-well 501. To the transistor forming region 40, therefore, arsenic is ion-implanted for threshold adjustment with the parameters of the implantation energy of 70 to 120 KeV and the implantation amount of 1×10¹³ to 3×10¹³ cm⁻² as a total.

After that, as shown in FIG. 5F, the thin gate oxide film 600 having a thickness of 2 to 5 nm is formed on the surface of the substrate 100, and a metal film is formed on the gate oxide film 600 and is patterned in a predetermined shape, thereby forming the gate electrode 601 having a gate length of 0.15 to 0.18 μm. After that, BF₂ is ion-implanted with the parameters of implantation energy of 3 to 10 KeV and an implantation amount of 5×10¹³ to 2×10^{14 cm}⁻² to the entire surface of the silicon substrate 100, thereby forming LDD regions 702 for P-channel transistors. Subsequently, arsenic is ion-implanted with the parameters of implantation energy of 50 to 100 KeV and the implantation amount of 1×10¹³ to 1×10¹⁴ cm⁻², thereby forming the pocket regions 703.

As shown in FIG. 5G, a resist film 304 is formed on the PMOS transistor forming regions 20 and 40. Arsenic is ion-implanted only to the NMOS transistor forming regions 10 and 30 with the parameters of implantation energy of 5 to 20 KeV and an implantation amount of 1×10¹⁴ to 1×10¹⁵ cm⁻². Subsequently, BF₂ is ion-implanted with the parameters of implantation energy of 20 to 50 KeV and an implantation amount of 1×10¹³ to 1×10¹⁴ cm⁻², thereby forming the LDD regions 700 and the pocket regions 701. In this case, by increasing the doping amount of arsenic ion to reverse the type of impurities in the LDD region 702 in the PMOS transistor from the p-type to the n-type, the LDD region 700 in the n-channel transistor is formed.

Further, in a manner similar to the LDD region 700 in the n-channel transistor, by reversing the type of impurities in the pocket region 703 in the PMOS transistor from the n-type to the p-type, the pocket region 701 in the NMOS transistor is formed. The formation of the LDD region 700 and the pocket region 701 in the NMOS transistor by inverting the type from the n-type to the p-type has an advantage such that the LDD region and the pocket region of each transistor can be formed by a single lithography process.

As shown in FIG. 5H, the gate side walls 602 each having a thickness of 80 to 150 nm are formed on side faces of each of the gate electrodes 601 by a known method. After that, as shown in FIG. 5I, a resist film 305 is formed on the PMOS transistor forming regions 20 and 40. Arsenic is ion-implanted with the parameters of implantation energy of 30 to 60 KeV and an implantation amount of 1×10¹⁵ to 2×10^{16 cm}⁻², thereby forming the source-drain regions 800 in the NMOS transistors.

Subsequently, as shown in FIG. 5J, a resist film 306 is formed on the NMOS transistor forming regions 10 and 30. By ion-implanting boron with the parameters of implantation energy of 1 to 10 KeV and an implantation amount of 1×10¹⁵ to 1×10^{16 cm}⁻², the source-drain regions 801 in the PMOS transistors are formed.

After that, by carrying out wiring and the like by a known method, a semiconductor device having the NMOS transistor and the PMOS transistor which operate with a low threshold and the NMOS transistor and the PMOS transistor each having a threshold optimized so as to minimize the off-state leak current is obtained.

In the embodiment, on the NMOS and PMOS transistors (second MOS transistors intended to operate with low power consumption) each having a threshold optimized so as to minimize the off-state leak current, the threshold is set by controlling a channel dose amount so that the minimum value of the drain current is the off-state leak current. As shown in FIG. 6, when the interband leak changes to the subthreshold leak, the minimum value of the drain current I_{off} appears. By setting the threshold so that the minimum value is the off-state leak current value, a MOS transistor having an extremely small off-state leak current can be formed.

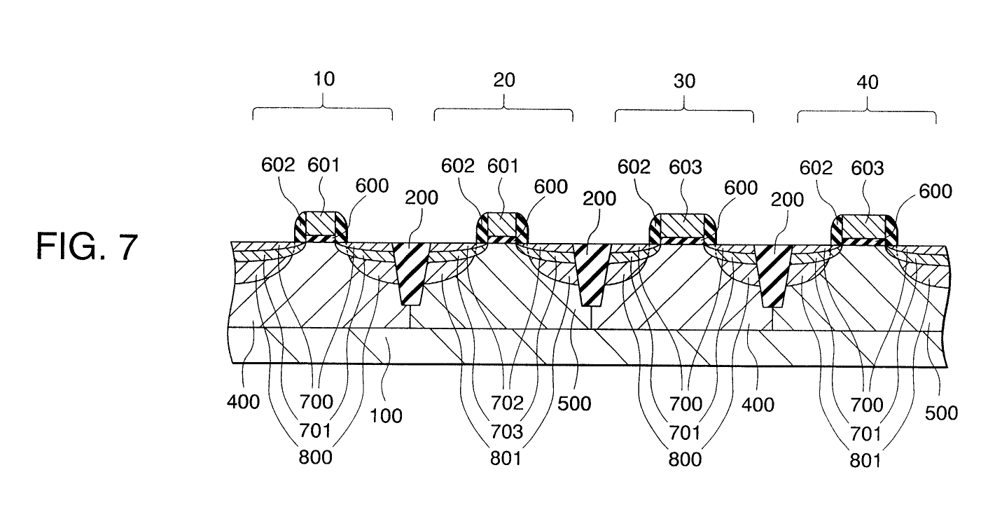

A second embodiment of the invention will now be described. FIG. 7 is a cross sectional view showing a semiconductor device of the embodiment. In the second embodiment shown in FIG. 7, the same components as those of the first embodiment shown in FIG. 5J are designated by the same reference numerals and their detailed description are omitted here. In the case of minimizing the off-state leak current of the MOS transistor, a predetermined threshold is set by adjusting the concentration of impurities in the channel region in the first embodiment. In the second embodiment, the threshold is adjusted by making the gate length of the MOS transistor longer. As shown in FIG. 7, in place of increasing the concentration of impurities in the channel region in each of the transistor forming regions 30 and 40, by forming second gate electrodes 603 each having a gate length longer than that of the electrode 601, the threshold can be increased. Further, in the embodiment as well, the threshold is adjusted by changing the gate length so that the minimum value of the drain current shown in FIG. 7 is the off-state leak current, and the off-state leak current can be minimized. By the arrangement, obviously, the object of the invention is achieved. Moreover, since only the gate length is changed, a synergistic effect such that it is unnecessary to add a process for changing the concentration of impurities in the channel region is produced.

The invention may be modified so as to obtain the off-state leak current which is the minimum value of the drain current by optimizing both the concentration of impurities in the channel region and the gate length.

In such a manner, on the basis of the fundamental configuration of setting the threshold so that the minimum value of the drain current of a MOS transistor is an off-state leak current, the invention can provide a semiconductor device suitable for an LSI of a low power consumption, in which an NMOS transistor and a PMOS transistor (second MOS transistors intended to operate with low power consumption) each having a threshold optimized so as to minimize the off-state leak current and an NMOS transistor and a PMOS transistor (second MOS transistors intended to operate at high speed) which operate with a low threshold can be formed on the same substrate. Obviously, the invention is not limited to the foregoing embodiments but the embodiments can be modified within the technical idea of the invention.

What is claimed is:

1. A semiconductor device comprising:
a semiconductor substrate;
a first MOS transistor formed on the semiconductor substrate; and
a second MOS transistor formed on the semiconductor substrate, having a threshold higher than that of the first MOS transistor,
wherein in the second MOS transistor, concentration of impurities in a channel region is set so that a minimum drain current appearing at the time of transition from a sub-threshold leak to an interband leak is a leak current in an off-state of the second MOS transistor.

2. A semiconductor device comprising:
a semiconductor substrate;
a first MOS transistor formed on the semiconductor substrate; and
a second MOS transistor formed on the semiconductor substrate, having a threshold higher than that of the first MOS transistor,
wherein in the second MOS transistor, gate length is set so that a minimum drain current appearing at the time of transition from a sub-threshold leak to an interband leak is a leak current in an off-state of the second MOS transistor.

3. A semiconductor device comprising:
a semiconductor substrate;
a first MOS transistor formed on the semiconductor substrate; and
a second MOS transistor formed on the semiconductor substrate, having a threshold higher than that of the first MOS transistor,
wherein in the second MOS transistor, concentration of impurities in a channel region and gate length are set so that a minimum drain current appearing at the time of transition from a sub-threshold leak to an interband leak is a leak current in an off-state of the second MOS transistor.

4. A method of fabricating a semiconductor device in which a first MOS transistor and a second MOS transistor having a threshold higher than that of the first MOS transistor are formed on the same substrate, comprising a step of setting concentration of impurities in a channel region in the second MOS transistor so that a minimum drain current appearing at the time of transition from a subthreshold leak to an interband leak is a leak current in an off-state of the second MOS transistor.

5. A method of fabricating a semiconductor device in which a first MOS transistor and a second MOS transistor having a threshold higher than that of the first MOS transistor are formed on the same substrate, comprising a step of setting gate length of the second MOS transistor so that a minimum drain current appearing at the time of transition from a sub-threshold leak to an interband leak is a leak current in an off-state of the second MOS transistor.

6. A method of fabricating a semiconductor device in which a first MOS transistor and a second MOS transistor having a threshold higher than that of the first MOS transistor are formed on the same substrate, comprising a step of setting concentration of impurities in a channel region and gate length in the second MOS transistor so that a minimum drain current appearing at the time of transition from a sub-threshold leak to an interband leak is a leak current in an off-state of the second MOS transistor.
